(19) United States
(12) Patent Application Publication
(10) Pub. No.: US 2005/0133806 A1
(43) Pub. Date: Jun. 23, 2005

(54) P and N contact pad layout designs of GaN based LEDs for flip chip packaging

(76) Inventors: Hui Peng, Fremont, CA (US); Gang Grant Peng, Fremont, CA (US)

Correspondence Address: Hui Peng, 35964 Vivian Place, Fremont, CA, 94536, US

(21) Appl. No.: 10/738,791

(22) Filed: Dec. 17, 2003

(51) Int. Cl. H01L 29/22

(52) U.S. Cl. 257/99

(57) ABSTRACT

Based on the unique properties of the flip chip packaging process and GaN based LEDs with transparent substrates, new principles and methods for designing the layout of P contact pads and N contact pads are disclosed. The new designs of the present invention drastically increase the light extraction efficiency of LEDs by reducing the current crowding effect, increasing the uniformity of the spreading current in the active layer, and utilizing most of the available light emitting semiconductor material of the active layer. The present invention combined with the flip chip packaging process significantly improves the LEDs' heat dissipation.

### BACKGROUND OF THE INVENTION

1. Field of the Invention

The present invention relates to new P and N contact pads layout designs of GaN based Light Emitting Diodes (LEDs) with transparent substrates for flip chip packaging and a new method of manufacturing the same. This invention drastically increases light extraction efficiency of GaN based LEDs. This invention makes a major improvement on the LED's heat dissipation.

2. Prior Art

There are three major issues for the LED design and manufacture: the current crowding effect, the heat dissipation problem, and the problem of a large contact pad blocking the emitted light.

Given the common LED die designs, the electrical current can't be evenly spread through the LED active layer or most of the current concentrates at a portion of the active layer (the current crowding effect). The current crowding effect is one of the primary limiting factors in LED die design and manufacture. It results in an unstable luminous flux output with drifting bright and dim spots on the LED chip and it prevents the effective usage of the available light emitting semiconductor material and the low quantum yield in term of the total active material. For high power LEDs, the current crowding effect limits the output luminous flux.

One of the approaches to reduce the currently crowding effect is to widen the current path by applying a current spreading layer. The effectiveness of the active layer depends on the current spread layer's thickness.

The flip chip packaging flips LED chips to face a submount with better thermal conductivity compared to the original substrate that the device is fabricated on. The flip chip packaging method completely eliminates the issue of large contact pads hindering the extraction of light and releases all the restrictions on the contact pad design that are related with the hindering effect. With the flip chip packaging method, the contact area of P and N contact pads can be designed very differently to minimize the current crowding effect and utilize the entire active layer.

There are varieties of prior art discussing flip chip packaging technology for gallium nitride (GaN) based LEDs with transparent substrate, including U.S. Pat. No. 6,483,196 B1 by Wojnarowski et al. for flip chip, U.S. Pat. No. 6,455,878 B1 by Bhat et al. for a low refractive index under fill, and U.S. Pat. No. 6,649,437 by Yang et al. for a manufacturing method. However there lacks of prior art that discloses other alternative P and N contact pad layout design rather than the conventional ones for GaN based LEDs with flip chip packaging. The advantages of applying flip chip packaging for the LEDs are far from having been realized and utilized. The increasingly demands to manufacture high efficiency and high power LEDs cost effectively requires new designs of P and N contact pads layout of GaN based LEDs.

### SUMMARY OF THE INVENTION

In the present invention, new principles, methods, and embodiments of new designs of P and N contact pad layout of GaN based LEDs with transparent substrate for flip chip packaging are disclosed.

The primary object and advantage of this invention is to provide new principles for designing P and N contact pad layout for flip chip packaging of GaN based LEDs with high extraction efficiency of emitted light.

The second object and advantage is to provide new P and N contact pad layout designs for efficiently utilizing light emitting material of active layer.

The third object and advantage is to provide new P and N contact pad layout designs for uniformly distributing the current and, thus increasing the current density.

The fourth object and advantage is to provide new P and N contact pad layout designs for more uniform and bright surface emission.

The fifth object and advantage is to provide new P and N contact pad layout designs for reducing current crowding effects.

The sixth object and advantage is to provide new P and N contact pad layout designs for generating less heat and improving heat dissipation when LEDs are flip chip bonded to a substrate with better thermal conductivity.

The seventh objective and advantage is to provide new P and N contact pad layout designs without employing current spreading layer.

Further objects and advantages of the present invention will become apparent from a consideration of the following description and drawings.

### BRIEF DESCRIPTION OF THE SEVERAL VIEWS OF DRAWINGS

The novel features believed characteristics of the present invention are set forth in the claims. The invention itself, as well as other features and advantages thereof will be best understood by referring to detailed descriptions that follow, when read in conjunction with the accompanying drawings.

FIG. 1a is a cross-sectional view of a GaN based LED of prior art.

FIG. 1b is a cross-sectional view of flip chip packaging of the GaN based LED of FIG. 1a bonded on a submount of prior art.

FIG. 2a is a top view of a preferred embodiment of new designed layout of LEDs with a P contact pad at the center portion.

FIG. 2b is a cross-sectional view of the LED of FIG. 2a.

FIG. 2c is a top view of a submount for bonding the LED of FIG. 2a to it.

FIG. 2d is a cross-sectional view of the LED mounted on the submount of FIG. 2c.

FIG. 2e is a top view of another submount with ball bumps for bonding the LED of FIG. 2a to it.

FIG. 2f is a cross-sectional view of the submount of FIG. 2e.

FIG. 3a is a top view of a preferred embodiment of new designed layout of LEDs with a N contact pad at the center portion.

FIG. 3b is a cross-sectional view of the LED of FIG. 3a.

FIG. 4a is a top view of a preferred embodiment of new designed layout of LEDs with a plurality of N contact pads surrounded by a P contact pad.

FIG. 4b is a top view of a preferred embodiment of new designed layout of LEDs with a plurality of P contact pad surrounded and separated by a cross-ring shaped N contact pad.

FIG. 4c is a top view of a preferred embodiment of new designed layout of LEDs with a plurality of triangle-shaped N contact pads respectively embedded in multiple P contact pads that is surrounded and separated by a cross-ring shaped N contact pad.

FIG. 4d is a top view of a preferred embodiment of new designed layout of LEDs with a plurality of P contact pads surrounded and separated by a N contact pad.

FIG. 5a is a top view of a preferred embodiment of new designed layout of LEDs with a N contact pad at the center portion.

FIG. 5b is a cross-sectional view of the LED of FIG. 5a.

FIG. 6a is a top view of a preferred embodiment of new designed layout of LEDs with a P contact pad at the center portion.

FIG. 6b is a cross-sectional view of the LED of FIG. 6a.

FIG. 6c is a top view of a submount for bonding the LED of FIG. 6a to it.

FIG. 7a is a top view of a preferred embodiment of new designed layout of LEDs with fork-shaped N and P contact pads.

FIG. 7b is a top view of a preferred embodiment of new designed layout of LEDs with fork-projection-shaped N contact pads.

FIG. 7c is a top view of a preferred embodiment of new designed layout of LEDs with more complicated fork-projection-shaped N contact pads.

FIG. 8a is a top view of a preferred embodiment of new designed layout of LEDs with a first P contact pad surrounded by a N contact pad which is surrounded by a second P contact pad.

FIG. 8b is a cross-sectional view of the LED of FIG. 8a.

FIG. 9a is a top view of a preferred embodiment of new designed layout of LEDs with a first N contact pad surrounded by a P contact pad which is surrounded by a second N contact pad.

FIG. 9b is a cross-sectional view of the LED of FIG. 9a.

FIG. 9c is a top view of a submount for bonding the LED of FIG. 9a to it.

FIG. 9d is a top view of a preferred embodiment of new designed layout LED with multiple P and N contact pads alternately surrounding each other.

### DETAILED DESCRIPTION OF THE INVENTION

With the application of the flip chip packaging process to LEDs layout design and manufacture, the conventional principles for P and N contact pad layout designs of GaN based LEDs need to be modified. The quantity, sizes, shapes, and positions of P and N contact pads all become useful variables for optimizing the contact pad layout designs. The designs of P and N contact pad layout of LEDs can be focused on certain issues such as the current crowding effect and the utilization of the light emitting semiconductor material of the active region.

The P contact pad can be designed with larger area and different shapes. The larger contact area will reduce the contact resistance and therefore the heat generation, because the contact resistance is inversely proportional to the contact area. Multiple P and N contact pads can be integrated into one LED die.

While embodiments of the present invention will be described below, those skilled in the art will recognize that other designs and methods are capable of implementing the principles and scope of the present invention. Thus the following description is illustrative only and not limiting.

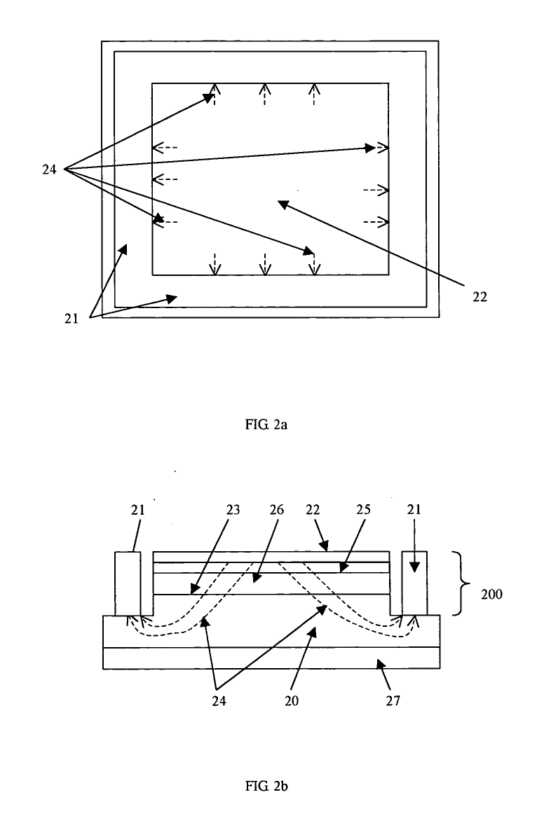

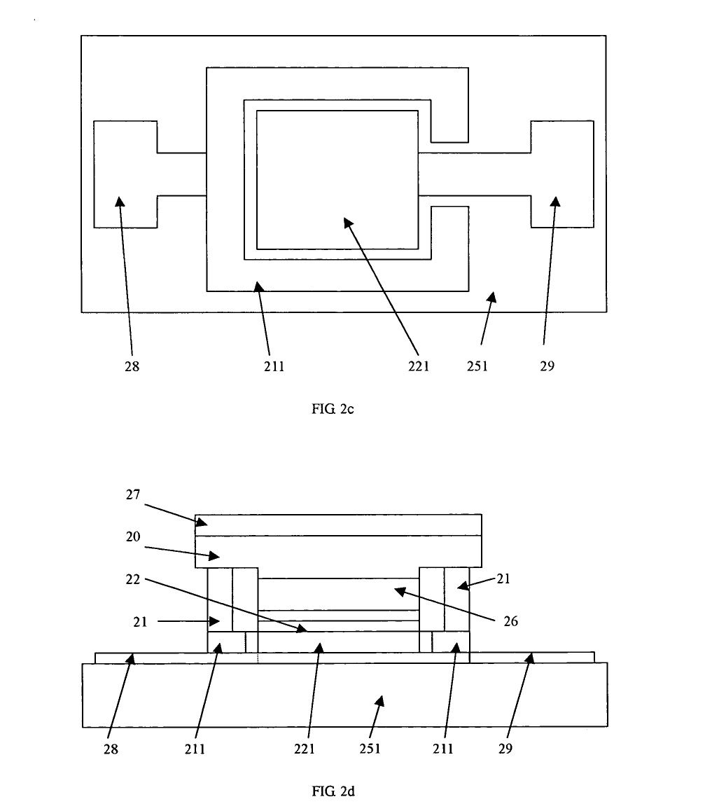

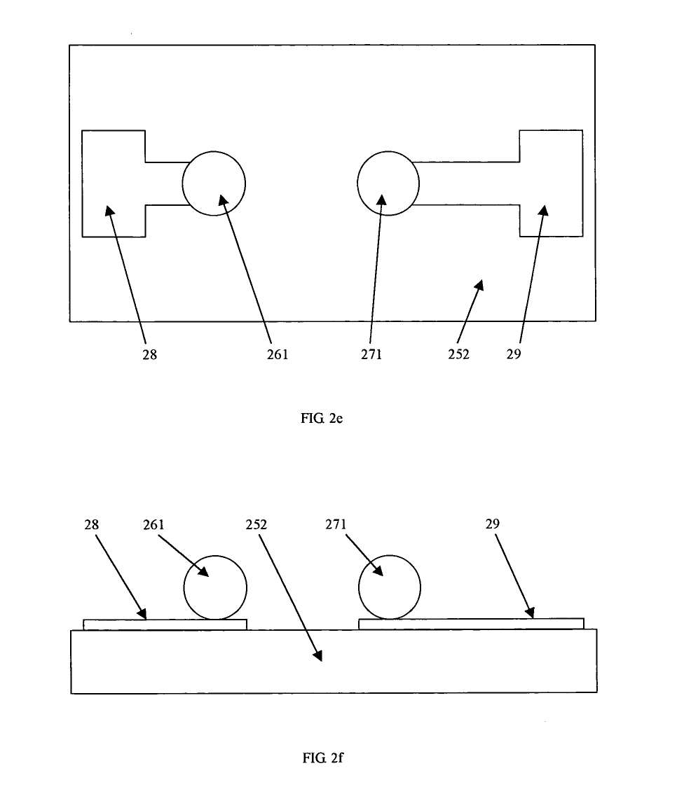

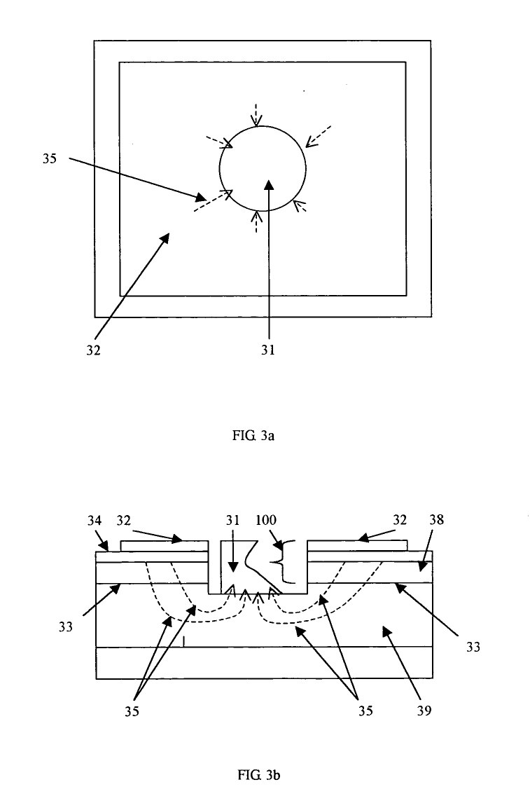

Note the followings that apply to all of new designed P and N contact pad layout of the present invention:
(1) The dimensions of all of drawings are not to scale;
(2) The P and N contact pads in each figure may have different shapes other than what shown in the figures.
(3) P contact pads and N contact pads may be interchanged and the current flow reversed and, then the LEDs are still function.
(4) Quantity of P and N contact pads of LEDs of the present invention may vary depending on the sizes of the LEDs and P and N contact pads. The area of N contact pad(s) is much smaller than that of P contact pad(s). Although separations between P and N contact pads are not shown in FIGS. 2a, 3a, 4a, 4b, 4c, 4d, 5a, 6a, 7a, 7b, 7c, 8a, 9a, and 9d, P contact pads and N contact pads in all of LEDs of the present invention are separated electrically by mesa edges. Mesa(s) is formed by a mesa etch process. Mesa is only showed in FIGS. 2b and 3b, since the space limitation. The current spreading layer on top of P confinement layer is no longer necessary, because P contact pads may be made as large as needed up to cover a large portion of or even the entire top surface of mesa(s).
(5) All of embodiments of LEDs of the present invention shown in FIG. 2 to FIG. 9 have the same epitaxial structure, i.e., an epitaxial layer is grown on a transparent substrate. The epitaxial layer comprises the P and the N confinement layers and an active region (or layer) sandwiched in between.
(6) There is a reflective layer between the P contact pad and the P confinement layer, which reflects the emitted light towards to substrate, although the reflective layer are not shown in some of FIGS.
(7) The design principles of the present invention may apply to other LEDs with different epitaxial structures as long as either the substrate is transparent or the non-transparent substrate is removed after flip chip bonding.
(8) A N contact pad is disposed on the N confinement layer and its elevation may be either lower than or equal to that of P contact pad.
(9) Although the P confinement layer is shown on top of the N confinement layer in all of cross-sectional views of preferred embodiments, their positions may be reversed for other preferred embodiments of the present invention.
(10) The P contact pads in new P and N contact pad layout designs of LEDs of the present invention are much larger than that of conventional LEDs, so that the LEDs have much better thermal performance.
(11) Four embodiments of submounts of the present invention are shown in FIGS. 2c, 2e, 6c, and 9c for the LEDs. However, following the same principles, submounts for all of LEDs with new P and N contact pad layout designs of the present invention may be designed without difficulty. The principles for design a submount are that positions and shapes of N bumps of the submount should match up with that of the corresponding N contact pads of LEDs and that N bumps are electrically connected to each other, although N pads of LEDs may not be electrically connected. It is similar design principle for the P bumps of a submount.
(12) The P and the N bumps on submounts may have different forms, the ball shape bump and the flat bonding surface bump. The present invention utilizes the major advantages of the flat bonding surface bumps over the ball bumps: (1) having significantly larger contact area (especially for the P bump); and (2) capable to integrate multiple P and N contact pads on one LED. The larger contact area of the bump and pad yields higher heat transfer rate, which is critical for the high power LEDs including the white LEDs. Depositing multiple P and N flat bonding surface bumps on a submount and making multiple P and N contact pads on one LED result in a better uniformity of the current distribution and spreading.

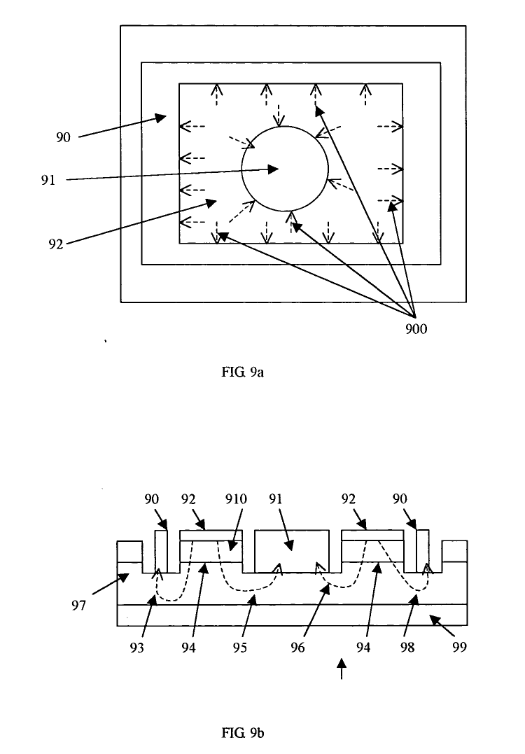

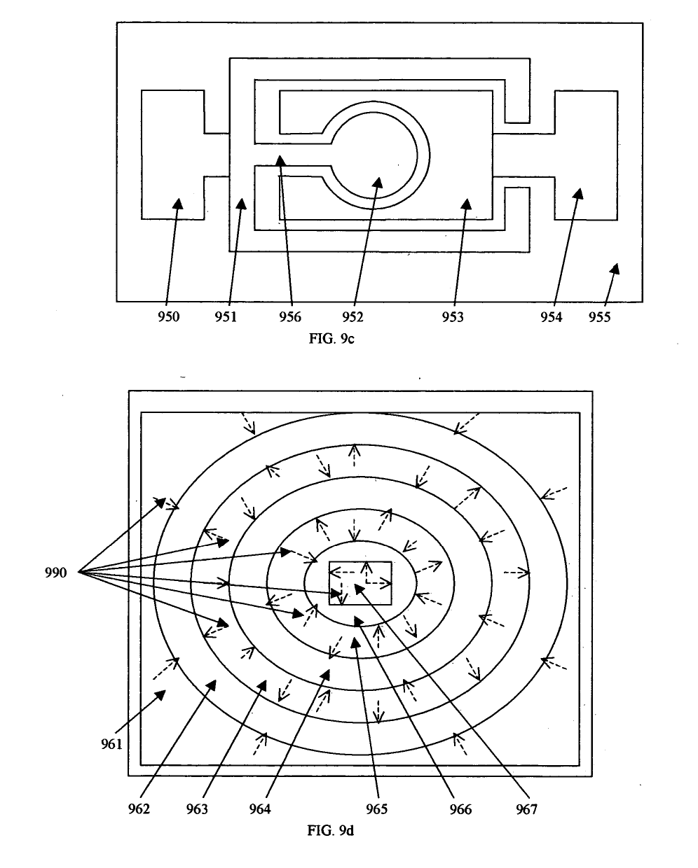

For a simple P and N contact pad layout design of LEDs, such as FIG. 2a, ball bumps on submount may be used to bond LEDs to submounts. For complex patterns of P and N contact pad layout designs, such as in FIG. 9d, the flat bonding surface bumps have to be used due to the limited surface area of LEDs and the minimum size of ball bump.
(13) The elevations of P bump, N bump, P contact pad, and N contact pad are determined such that both P and N contact pads of LEDs can be bonded simultaneously to their corresponding bump of a submount when a LED flip chip bonded to the submount. The top surface of N contact pad may be either in the same elevation as P contact pad or lower.

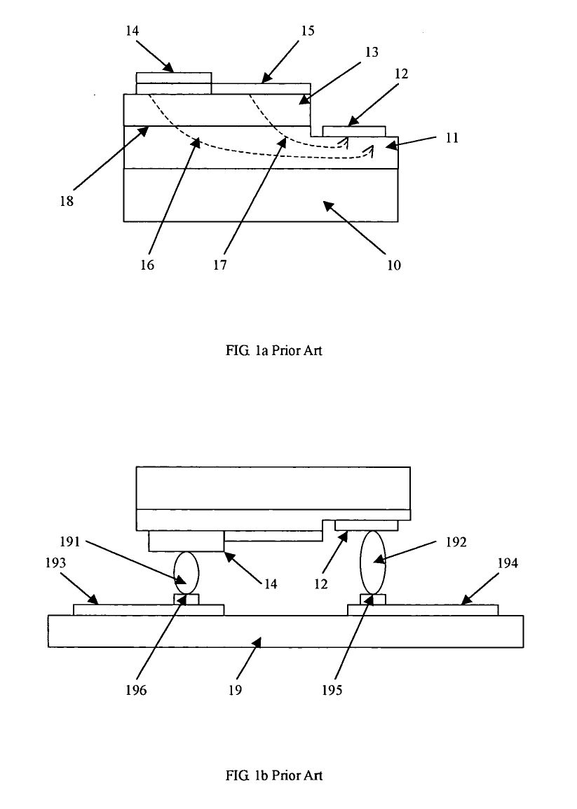

FIG. 1a is a cross-sectional view of a GaN base LED of prior art. N confinement layer 11 is grown on substrate 10 and etched at one side for depositing N contact pad 12. P contact pad 14 is grown on P confinement layer 13. There is current spreading layer 15 deposited on P confinement layer 13. When powered up the LED, current 16 and current 17 flow respectively from P contact pad 14 and current spreading layer 15 to N contact pad 12. P contact pad 14 sizing about 100 micrometer blocks light emitted from the active region. Current spreading layer 15 is not fully transparent and, therefore, it blocks the emitted light too.

FIG. 1b shows a flip chip packaging of the LED of FIG. 1 a on submount 19. Bump bonding pad 196 and 195 connect to P bonding pad 193 and N bonding pad 194 respectively. Ball bump 191 bonds bump bonding pad 196 to P contact pad 14. Ball bump 192 bonds bump bonding pad 195 to N contact pad 12. The minimum size of ball bumps can introduce restrictions on P and N contact pad layout design.

FIG. 2a is a top view of a LED of the present invention with P contact pad 22 at the center portion of the LED. N contact pad 21 surrounds P contact pad 22. Note that the P and N contact pads in this layout design may have other shapes, such as circular. Dotted current flow line 24 shows the direction of current flow.

FIG. 2b shows a cross-sectional view of the LED in FIG. 2a. N confinement layer 20 disposes on substrate 27. P confinement layer 26 grows on active region 23 that disposes on N confinement layer 20. P contact pad 22 disposes on reflective layer 25 that is on P confinement layer 26. N contact pad 21 contacts N confinement layer 20 by etching down to N confinement layer 20 first. The etching process generates mesa 200. The edge of the mesa 200 separates P contact pad 22 from N contact pad 21. The current 24 flows from P contact pad 22 to N contact pad 21 through active region 23.

Note that the elevation of N contact pad 21 is the same as that of P contact pad in FIG. 2b, however, it can be lower.

FIG. 2c shows a top view of an embodiment of submount 251 for the LED of FIG. 2a to be bonded on. N bonding pad 28 and P bonding pad 29 are disposed on submount 251. N bonding pad 28 connects electrically with N flat bonding surface bump 211 and is for wire bonding to external power source. P bonding pad 29 connects electrically with P flat bonding surface bump 221 and is for wire bonding to external power source. N and P bonding pad 28 and 29 are separated electrically. N flat bonding surface bump 211 is electrically separated from P flat bonding surface bump 221.

FIG. 2d is a cross-sectional view of the LED of FIG. 2a mounted on submount 251. The LED of FIG. 2a is flip chip bonded to submount 251. P and N contact pad 22 and 21 are respectively bonded to P flat bonding surface bump 221 and N flat bonding surface bump 211. It is more efficiency way to transfer the heat from the LED to the submount, because a larger area of the LED is bonded to the submount by the soldering metal instead of the underfill organic polymer. The elevations of both N flat bonding surface bump 211 and P flat bonding surface bump 221 are higher than that of N and P bonding pad 28 and 29.

Note that the elevations of P flat bonding surface bump 221, N flat bonding surface bump 211, P contact pad 22, and N contact pad 21 are so determined that P flat bonding surface bump 221 and N flat bonding surface bump 211 are respectively bonded to P contact pad 22 and N contact pad 21.

FIG. 2e shows a top view of another embodiment of submount for the LED of FIG. 2a to be bonded on. N bonding pad 28 and P bonding pad 29 dispose on submount 252. N bonding pad 28 connects electrically with N ball bump 261 and is for wire bonding to external power source. P bonding pad 29 connects electrically with P ball bump 271 and is for wire bonding.

FIG. 2f is a cross-sectional view of submount 252. P and N ball bump 261 and 271 are ball shape like the ball bumps for conventional flip chip packaging.

The elevations of the top surface of both N ball bump 261 and P ball bump 271 may be different, depending on the elevations of N contact pad 21 and P contact pad 22 of the LED of FIG. 2a.

FIG. 3a is a top view of a LED. N contact pad 31 is at the center portion of the LED and surrounded by P contact pad 32. P and N contact pad 32 and 31 may be in different shapes respectively. Dotted current flow line 35 indicates the direction of current flow.

FIG. 3b is a cross-sectional view of the LED of FIG. 3a. Current 35 flows from P contact pad 32 to N contact pad 31 through active layer 33. N contact pad 31 is disposed on N confinement layer 39. Reflective layer 34 is sandwiched between P contact pad 32 and P confinement layer 38.

In FIG. 3b, only a portion of N contact pad 31 is shown, since space is need to place symbol “{” for indicating mesa 100.

Quantity of each of P and N contact pads in FIG. 2a and FIG. 3a may be more than one as long as P and N contact pads are separated and alternately surrounded by each other.

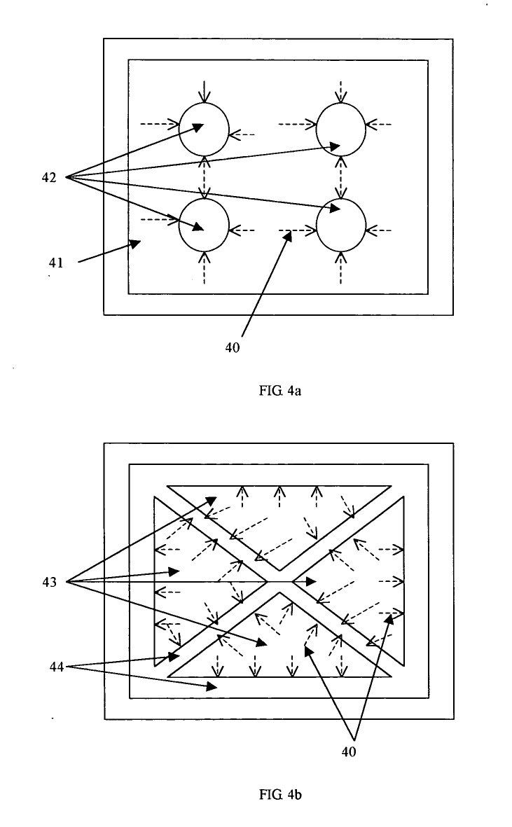

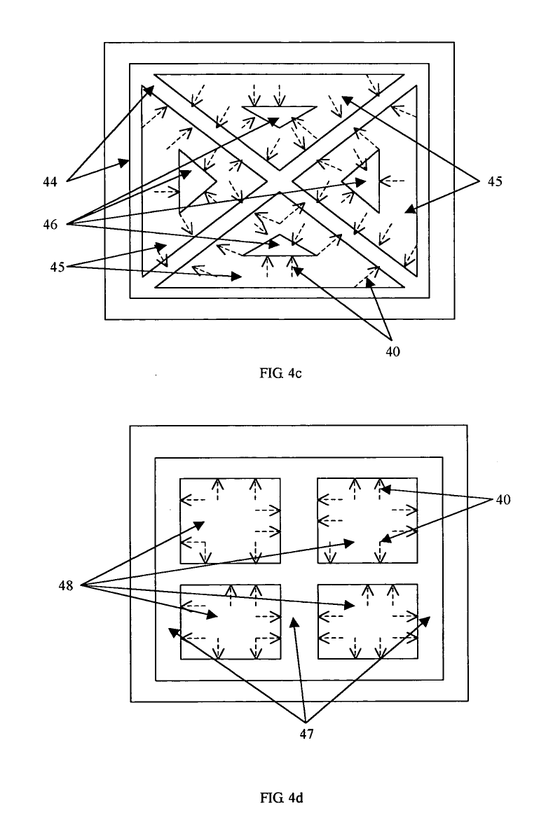

FIG. 4a shows a new designed layout for a LED of the present invention. A plurality of N contact pad 42 are separated and surrounded by P contact pad 41. N contact pads 42 may be in different shapes, such as rectangular. Quantity of N contact pads may be either more or less than 4. Dotted current flow line 40 in FIG. 4a to FIG. 4d indicates the direction of current flow.

FIG. 4b shows a new designed layout of a LED of the present invention. There are four of triangle-shaped P contact pad 43 separated by cross-ring shaped N contact pad 44. P contact pad 43 may be in different shape, such as circular. Quantity of P contact pad 43 may be either more or less than 4.

FIG. 4c shows a new designed layout of a LED with four of triangle-shaped N contact pad 46 embedded in four of triangle-shaped P contact pad 45 respectively. Multiple P contact pad 45 are separated by cross-ring shaped N contact pad 44.

FIG. 4d shows a new design for LEDs. Four of rectangular-shaped P contact pad 48 are separated and surrounded by cross-ring shaped N contact pad 47. Quantity of P contact pads may be more or less than 4. P contact pad 48 may be in different shape, such as circular. Submounts may be designed for the LED of FIG. 4a to 4d. Quantity and positions of N and P flat bonding surface bumps on the submount need to match that of multiple N and P contact pads respectively. All the N and P flat bonding surface bumps need to be electrically connected respectively.

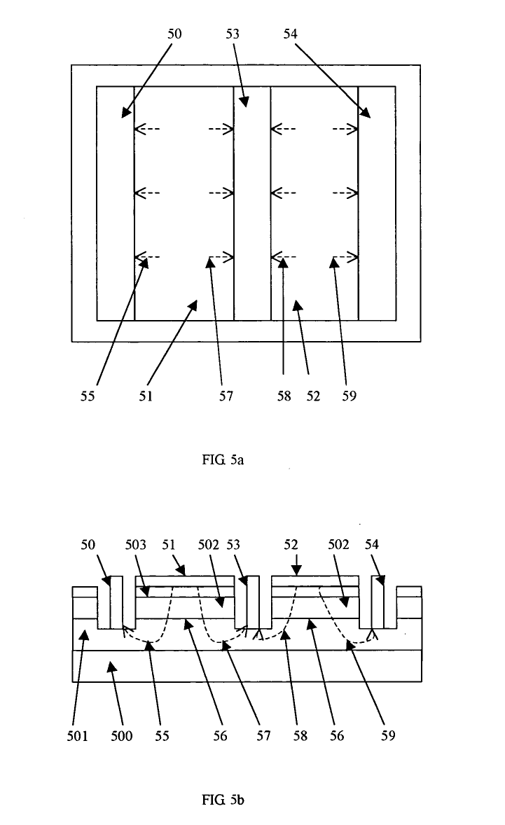

FIG. 5a shows a top view of a LED with stripe-shaped N contact pad 50, 53, 54, and P contact pad 51 and 52. N contact pad 50, 53, and 54 are separated by P contact pad 51 and 52 respectively. Dotted current flow line 55, 57, 58, and 59 indicate the direction of current flow.

FIG. 5b is a cross-sectional view of the LED of FIG. 5a. Current 55 flows from P contact pad 51 to N contact pad 50 through active region 56. Current 57 flows from P contact pad 51 to N contact pad 53 through active region 56. Current 58 flows from P contact pad 52 to N contact pad 53 through active region 56. Current 59 flows from P contact pad 52 to N contact pad 54 through active region 56. Reflective layer 503 is sandwiched between P confinement layer 502 and both of P contact pad 51 and 52. Active layer 56 disposes between P confinement 502 and N confinement 501 that is grown on substrate 500.

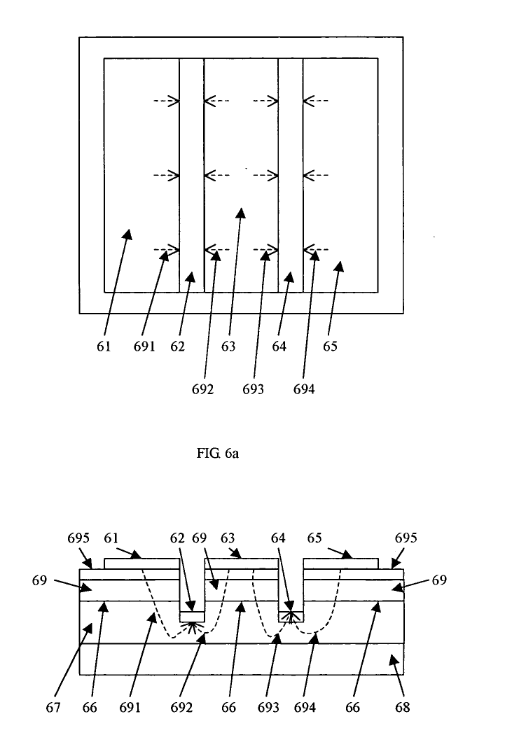

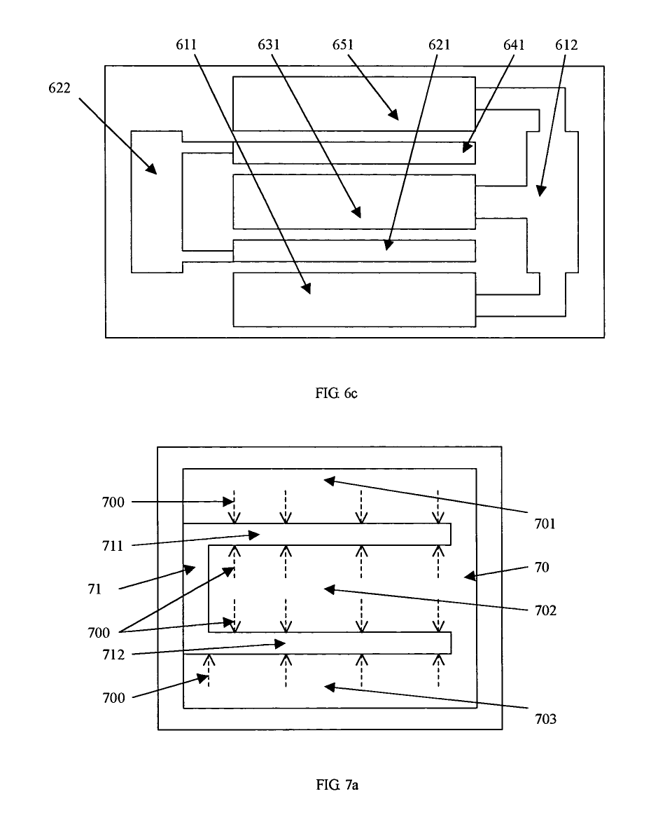

While N contact pad 53 is at the center portion of a LED in FIG. 5a, FIG. 6a shows a LED with P contact pad 63 at the center portion. P contact pad 61, 63, and 65 are separated by N contact pad 62 and 64 respectively. Dotted current flow line 691, 692, 693, and 694 indicate the direction of current flow.

FIG. 6b is a cross-sectional view of a LED of FIG. 6a. Current 691 flows from P contact pad 61 to N contact pad 62 through active region 66. Current 692 flows from P contact pad 63 to N contact pad 62 through active region 66. Current 693 flows from P contact pad 63 to N contact pad 64 through active region 66. Current 694 flows from P contact pad 65 to N contact pad 64 through active region 66. Reflective layer 695 is sandwiched between P confinement layer 69 and three of P contact layer 61, 63, and 65. Active layer 66 is between P confinement layer 69 and N confinement layer 67 that is grown on substrate 68.

Note that quantity of N pads and P pads may be either more or less than what shown in FIG. 5 and FIG. 6 respectively, depending on the sizes of P and N contact pads and LEDs.

The elevations of N contact pad 62 and 64 are lower than that of P contact pad 61, 63, and 65. However the elevations of N contact pads may be the same as that of P contact pads.

With either narrowed sizes of P and N contact pads or a LED with larger surface area (this is the case of high power LED), more P and N contact pads may be disposed on the LED as long as they are separated by each other. Therefore, uniformed current distribution and spreading can be achieved.

FIG. 6c is a top view of a submount for the LED of FIG. 6a to bond on. P flat bonding surface bump 611, 631, and 651 disposed on the submount are electrically connected to P bonding pad 612 and will be bonded to P contact pad 61, 63, and 65 respectively. N flat bonding surface bump 621 and 641 disposed on the submount are electrically connected to N bonding pad 622 and will be bonded to N contact pad 62 and 64 respectively. P and N bonding pads 612 and 622 are for wire bonding to external power source.

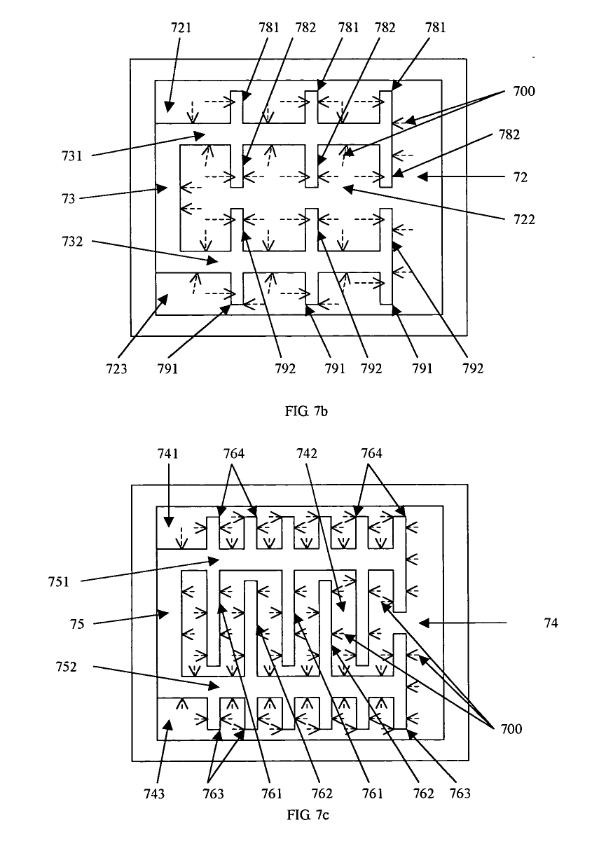

FIG. 7a shows a new designed LED that comprises fork-shaped P contact pad 70 and fork-shaped N contact pad 71. Fork-shaped P contact pad 70 has three legs, P leg 701, 702, and 703. Fork-shaped N contact pad 71 has two legs, N leg 711 and 712. P leg and N leg point to opposite directions. At least portions of N leg 711 and 712 are interspersed with and separated from portions of P leg 701, 702, and 703. P leg 701, 702, and 703 are electrically connected. N leg 711 and 712 are electrically connected. Current flows from P leg 701 and 702 to N leg 711. Current flows from P leg 702 and 703 to N leg 712. Dotted current flow line 700 indicates the direction of current flow.

FIG. 7b is a layout of a fork-projection-shaped LED that comprising P and N fork 72 and 73. P fork 72 have P leg 721, 722, and 723. N fork 73 has N leg 731 and 732. P leg 721, 722, and 723 are separated by N leg 731 and 732 respectively. Projection 791 and 792 of N leg 732 extend into opposite directions and into P leg 723 and 722 respectively. Projection 781 and 782 of N leg 731 extend into opposite directions and into P leg 721 and 722 respectively. Dotted current flow line 700 show the direction of current flow. Current flows from P leg 721 and 722 to N leg 731 and its projections. Current flows from P leg 722 and 723 to N leg 732 and its projections.

Note each of the P and N forks may have different number of P and N legs. N legs may have either more or less projections.

FIG. 7c is a modification of LED layout design of FIG. 7b. P fork 74 has P leg 741, 742, and 743. N fork 75 has N leg 751 and 752. P leg 741, 742, and 743 are separated by N leg 751 and 752 respectively. Projection 763 and 762 of N leg 752 extend into opposite directions and into P leg 743 and 742 respectively. Projection 761 and 764 of N leg 751 extend into opposite directions and into P leg 742 and 741 respectively.

A portion of Projection 762 of N leg 752 of N contact pad 75 is disposed between and spaced apart from respective portion of two of projection 761 of N leg 751. Other projections are disposed in the same way. Dotted current flow line 700 show the direction of current flow. In this layout, the current distribution and spreading are more uniform.

Note that depending on the sizes of LEDs, P and N legs, and projections, especially for high power LED with larger die size, fork-shaped P and N contact pads may have more P legs and N legs in order to have current distribution and spreading uniformly. P and N legs may have more projections. The quantity of projections of legs and legs of contact pads are not limited to what shown in FIG. 7b and 7c. Projections may also extend from P legs of P contact pad into N legs.

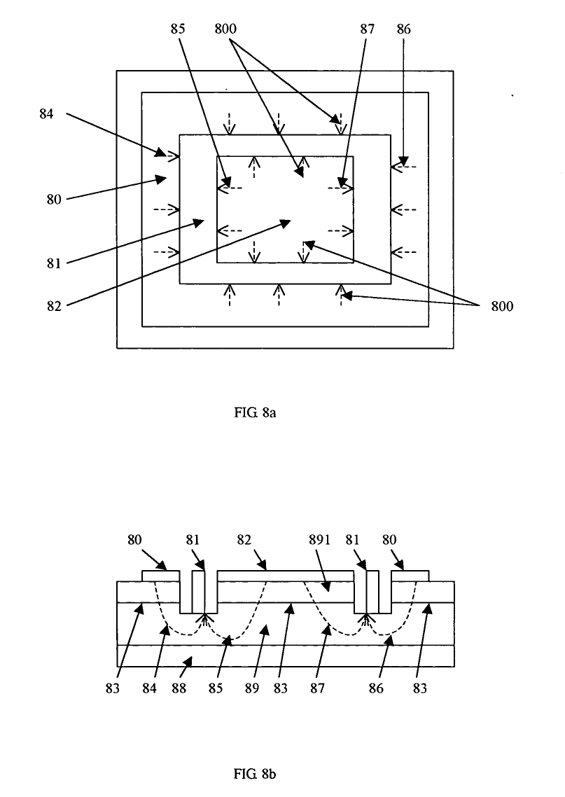

FIG. 8a shows a new designed LED. There is first P contact pad 82 surrounded by N contact pad 81 that is surrounded by second P contact pad 80. Dotted current flow line 800, 84, 85, 86, and 87 indicate the direction of current flow.

FIG. 8b is the cross-sectional view of the LED of FIG. 8a. Current 84 and 85 respectively flow from P contact pad 80 and 82 to N contact pad 81 through active region 83. Current 86 and 87 respectively flow from P contact pad 80 and 82 to N contact pad 81 through active region 83. The reflective layer disposed between P contact pad 82 and 80 and P confinement layer 891 is not shown in FIG. 8b. N confinement layer 89 is disposed on substrate 88.

FIG. 9a shows a new designed LED. There is first N contact pad 91 surrounded by P contact pad 92 which is surrounded by second N contact pad 90. Dotted current flow line 900 indicates the direction of current flow.

FIG. 9b is the cross-sectional view of the LED of FIG. 9a. N confinement layer 97 is disposed on substrate 99. Active layer 94 is sandwiched between P and N confinement layer 910 and 97. P contact pad 92 is disposed on P confinement layer 910. A reflective layer (not shown in FIG. 9b) is disposed between P contact pad 92 and P confinement layer 910. Current 93 and 95 flow from P contact pad 92 to N contact pad 90 and 91 respectively through active region 94. Current 96 and 98 flow from P contact pad 92 to N contact pad 91 and 90 respectively through active region 94.

FIG. 9c shows a top view of submount 955 for the LED of FIG. 9a to be bonded on. N bonding pad 950 and P bonding pad 954 are disposed on submount 955 respectively and not electrically connected. N flat bonding surface bump 951, Circle 952, and bridge 956 are electrically contacted to N bonding pad 950. P flat bonding surface bump 953 is electrically contacted to P bonding pad 954. The elevations of N flat bonding surface bump 951, circle 952, bridge 956 and P flat bonding surface bump 953 are the same and higher than that of both P and N bonding pad 950 and 954.

When flip chip bonding the LED of FIG. 9a to substrate 955, N contact pad 91 and 90 are bonded to circle 952 and N flat bonding surface bump 951 respectively. P contact pad 92 is bonded to P flat bonding surface bump 953. FIG. 9d shows an embodiment of the present invention. A LED has a plurality of P contact pad 961, 963, 965, and 967, and a plurality of N contact pad 962, 964, and 966. Multiple P contact pads and multiple N contact pads are alternately surrounding each other. Note that P and N contact pads may have different shapes respectively. Quantity of P and N contact pads may be either more or less than what are showed in FIG. 9d. Positions of P and N contact pads are interchangeable. Dimensions of P and N contact pads are not to scale.

For the LEDs with larger surface area, especially for high power LEDs, there may be more P and N contact pads surrounding alternately each other so that the current distributes and spreads more uniformly.

Note that combinations of P and N contact pad layout designs of FIG. 2 to FIG. 9 are equivalent to the new P and N contact pad layout designs of the present invention.

It should be emphasized that although the description above contains many specifications, these should not be constructed as limiting the scope of the present invention. They just provide the illustrations of some of the presently preferred embodiments of the present invention.

Variations and modifications may be made to the above-described embodiments of the present invention without departing from the principles of the invention. All of such modifications and variations are included within the scope of the present invention and protected by the following claims.

Therefore the scope of the present invention should be determined by the claims and their legal equivalents.

1. A flip chip package of a semiconductor light emitting diode, comprising:
a transparent substrate;
a light emitting structure grown on said substrate;
wherein said light emitting structure comprising a first confinement layer, an active region, and a second confinement layer;
at least one first contact pad in contact with said first confinement layer;
at least one second contact pad in contact with said second confinement layer;
a mesa formed by a mesa etch process on said semiconductor light emitting diode;
wherein said second contact pad separated from said first contact pad by an edge of said mesa;
wherein said second contact pad covering large portion to whole of top surface area of said mesa;
a submount;
wherein said submount comprising at least one first flat bonding surface bumps with shape and position matching up with that of said first contact pad of said LED;
wherein said submount comprising at least one second flat bonding surface bump with shape and position matching up with that of said second contact pad of said LED;
said first flat bonding surface bumps and said second flat bonding surface bump disposed on said submount and separated electrically.

2. The semiconductor light emitting diode of claim 1, wherein the elevation of the top surface of said first contact pad is the same as the elevation of the top surface of said second contact pad.

3. The semiconductor light emitting diode of claim 1, wherein said second contact pad is at the center portion of said semiconductor light emitting diode and surrounded by said first contact pad.

4. The semiconductor light emitting diode of claim 3, further comprises a second said second contact pad surrounding said first contact pad.

5. The semiconductor light emitting diode of claim 3, wherein said second contact pad has a shape of rectangular.

6. The semiconductor light emitting diode of claim 1, wherein said first contact pad is at the center portion of said semiconductor light emitting diode and surrounded by said second contact pad.

7. The semiconductor light emitting diode of claim 6, further comprises a second said first contact pad surrounding said second contact pad.

8. The semiconductor light emitting diode of claim 6, wherein said first contact pad has a shape of circular.

9. The semiconductor light emitting diode of claim 1, further comprises a plurality of said second contact pads separated and surrounded by said first contact pad.

10. The semiconductor light emitting diode of claim 9, wherein said plurality of said second contact pads have a shape of rectangular.

11. The semiconductor light emitting diode of claim 9, wherein said first contact pad is in a cross-ring shape.

12. The semiconductor light emitting diode of claim 9, further comprises a plurality of said first contact pads embedded in said second contact pads respectively.

13. The semiconductor light emitting diode of claim 1, further comprises a plurality of said first contact pads separated and surrounded by said second contact pad.

14. The semiconductor light emitting diode of claim 13, wherein said plurality of said first contact pads have a shape of circular.

15. The semiconductor light emitting diode of claim 13, further comprises a plurality of said second contact pads embedded in said first contact pads respectively.

16. The semiconductor light emitting diode of claim 1, further comprises a plurality of said first contact pads and a plurality of said second contact pads; and wherein said plurality of said first contact pads and said plurality of said second contact pads are separated by said mesa.

17. The semiconductor light emitting diode of claim 16, wherein both said plurality of said first contact pads and said plurality of said second contact pads have the shapes of stripe.

18. The semiconductor light emitting diode of claim 16, wherein both said plurality of said first contact pads and said plurality of said second contact pads have the shapes of ring and are separated and alternately surrounded by each other.

19. The semiconductor light emitting diode of claim 1, wherein both said first contact pads and said second contact pad have the shape of fork and each of said first contact pad and said second contact pad comprises at least two legs.

20. The semiconductor light emitting diode of claim 19, wherein a portion of one of said legs of one of both said first contact pad and said second contact pad is disposed between and electrically separated from respective portion of two of said legs of another said contact pad.

21. The semiconductor light emitting diode of claim 19, further comprises at least one projection on each of said legs.

22. The semiconductor light emitting diode of claim 21, further comprises a plurality of said projections on each of said legs.

23. The semiconductor light emitting diode of claim 22, wherein a portion of one of said projections of one of said legs of one of said contact pads is disposed between and electrically separated from respective portion of two of said projections of another said legs of said one of said contact pad.

24. The semiconductor light emitting diode of claim 1, further comprises a reflective layer disposed between said second contact pad and said second confinement layer.

25. (canceled)

26. (canceled)

27. (canceled)

28. The submount of claim 1, further comprises a plurality of said first flat bonding surface bumps; wherein the shapes and positions of said plurality of said first flat bonding surface bumps matching up with that of corresponding first contact pads of a LED; wherein said plurality of said first flat bonding surface bumps being electrically connected and correspondingly bonding to said first contact pads of said LED respectively.

29. The submount of claim 1, further comprises a plurality of said second flat bonding surface bumps; wherein the shapes and positions of said plurality of said second flat bonding surface bumps matching up with that of corresponding second contact pads of a LED; wherein said plurality of said second flat bonding surface bumps being electrically connected and correspondingly bonding to said second contact pads of said LED respectively.
